(19) United States
(12) Patent Application Publication
(10) Pub. No.: US 2025/0267246 A1
(43) Pub. Date: Aug. 21, 2025

(54) STEREOSCOPIC IMAGE DISPLAY DEVICE

(71) Applicant: LG DISPLAY CO., LTD., Seoul (KR)

(72) Inventor: DongSoo SHIN, Paju-si (KR)

(73) Assignee: LG DISPLAY CO., LTD., Seoul (KR)

(21) Appl. No.: 18/790,833

(22) Filed: Jul. 31, 2024

(30) Foreign Application Priority Data
Feb. 21, 2024 (KR) 10-2024-0024887

(51) Int. Cl. H04N 13/305; H01L 25/075

(52) U.S. Cl. CPC H04N 13/305; H01L 25/0753; H04N 2213/001

(57) ABSTRACT

According to an embodiment of the present disclosure, a stereoscopic image display device can be provided. The stereoscopic image display device can include a display panel configured to display an image, and a lens unit disposed on one surface of the display panel, and disposed to be inclined at a preset angle from the display panel. In addition, the lens unit can be configured to implement stereoscopic image. Additionally, according to another embodiment, the stereoscopic image display device can include a display panel configured to display an image, a plurality of micro light emitting diodes (LEDs) disposed on the display panel, and a plurality of lenticular lenses disposed on the display panel. In addition, the plurality of lenticular lenses can be configured to implement a stereoscopic image.

### CROSS-REFERENCE TO RELATED APPLICATION

This application claims priority to Korean Patent Application No. 10-2024-0024887, filed on Feb. 21, 2024, in the Republic of Korea, which is hereby incorporated by reference for all purposes as if fully set forth herein.

### BACKGROUND

### 1. Field

Embodiments of the disclosure relate to a stereoscopic image display device.

### 2. Description of Related Art

Recent increased user demand for real-like and immersive images leads to development of stereoscopic image display devices capable of displaying three-dimensional (3D) images that deliver a 3D effect to viewers.

In general, two-dimensional (2D) image display devices have made great progress in terms of display image quality such as resolution and viewing angle, but have limitations of being incapable of displaying image depth information. On the other hand, stereoscopic image display devices can provide users with more realistic images than 2D display devices by displaying images in 3D.

The stereoscopic image display devices can configure a single screen that allows the user to receive different screens through the left and right eyes, and then superimpose the screen information in the cerebrum to provide a stereoscopic effect such as front and back, up and down, left and right, and perspective. Accordingly, the stereoscopic image display devices are configured to show a 3D effect to viewers.

The stereoscopic image display devices can be divided into a glasses type that uses stereoscopic glasses and a glasses-free type that does not use stereoscopic glasses. The glasses-free type stereoscopic image display device is the same as the glasses-type in that it gives the user a 3D effect of the image using binocular parallax, but has an advantage in that there is no need to wear stereoscopic glasses.

However, the glasses-free type stereoscopic image display device can suffer from image stuttering or looking unnatural when switching views. Accordingly, there is a problem that the glasses-free type stereoscopic image display device can show a lower quality image.

### SUMMARY OF THE DISCLOSURE

According to embodiments of the present disclosure, there can be provided a stereoscopic image display device capable of displaying a 2D image, output from a display panel, as a 3D stereoscopic image by independently disposing a lenticular lens in one pixel area.

According to embodiments of the present disclosure, there can be provided a stereoscopic image display device in which the subpixel and the lens unit are not superposed by disposing the lens unit on the subpixel of the display panel in a slanted type to thereby reduce generation of moiré patterns.

According to embodiments of the present disclosure, there can be provided a stereoscopic image display device capable of smooth image switching while switching views by making the view boundary unclear by disposing the lens unit on the subpixel of the display panel in a slanted type.

According to embodiments of the present disclosure, there can be provided a stereoscopic image display device capable of configuring various view maps depending on angle settings of the lens unit by subdividing the view map in various directions by disposing the lens unit on the subpixel of the display panel in a slanted type.

According to embodiments of the present disclosure, there can be provided a stereoscopic image display device capable of enhancing visibility while preventing glare by reducing the reflectance of external light by providing an anti-reflection layer on the lens unit.

According to embodiments of the present disclosure, there can be provided a stereoscopic image display device including a display panel displaying an image, a lens unit disposed on one surface of the display panel, and formed to be inclined at a preset angle from the display panel, and an adhesive layer disposed between the display panel and the lens unit.

According to embodiments of the present disclosure, there can be provided a stereoscopic image display device including a display panel including a pixel area and a non-pixel area disposed around the pixel area, a lens unit disposed on one surface of the display panel, and independently disposed in the pixel area, and an adhesive layer disposed between the display panel and the lens unit.

According to embodiments of the present disclosure, there can be provided a stereoscopic image display device capable of displaying a 2D image, output from a display panel, as a 3D stereoscopic image by independently disposing a lenticular lens in one pixel area.

According to embodiments of the present disclosure, there can be provided a stereoscopic image display device in which the subpixel and the lens unit are not superposed by disposing the lens unit on the subpixel of the display panel in a slanted type to thereby reduce generation of moiré patterns.

According to embodiments of the present disclosure, there can be provided a stereoscopic image display device capable of smooth image switching while switching views by making the view boundary unclear by disposing the lens unit on the subpixel of the display panel in a slanted type.

According to embodiments of the present disclosure, there can be provided a stereoscopic image display device capable of configuring various view maps depending on angle settings of the lens unit by subdividing the view map in various directions by disposing the lens unit on the subpixel of the display panel in a slanted type.

According to embodiments of the present disclosure, there can be provided a stereoscopic image display device capable of enhancing visibility while preventing glare by reducing the reflectance of external light by providing an anti-reflection layer on the lens unit.

According to embodiments of the present disclosure, there can be provided a stereoscopic image display device with reduced power consumption by applying low-power micro light-emitting diodes (LEDs) as light emitting elements of the display panel.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a block diagram illustrating a system of a stereoscopic image display device according to an embodiment of the present disclosure;

FIG. 2 is a perspective view illustrating a configuration of a stereoscopic image display device according to an embodiment of the present disclosure;

FIG. 3 is a cross-sectional view illustrating a stereoscopic image display device according to an embodiment of the present disclosure;

FIG. 4 is a plan view illustrating a lens unit disposed in a pixel area according to an embodiment of the present disclosure;

FIG. 5 is a view schematically illustrating moiré interference depending on the presence or absence of a slope of a lens unit;

FIG. 6 is a view schematically illustrating view switching depending on the presence or absence of a slope of a lens unit;

FIG. 7 is a view schematically illustrating a luminance variance per viewing angle depending on the presence or absence of a slope of a lens unit; and

FIG. 8 is a view schematically illustrating a view map depending on the presence or absence of a slope of a lens unit.

### DETAILED DESCRIPTION OF THE EMBODIMENTS

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements, etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”. Additionally, all the components of each display device according to all embodiments of the present disclosure are operatively coupled and configured.

Hereinafter, various embodiments of the disclosure are described in detail with reference to the accompanying drawings.

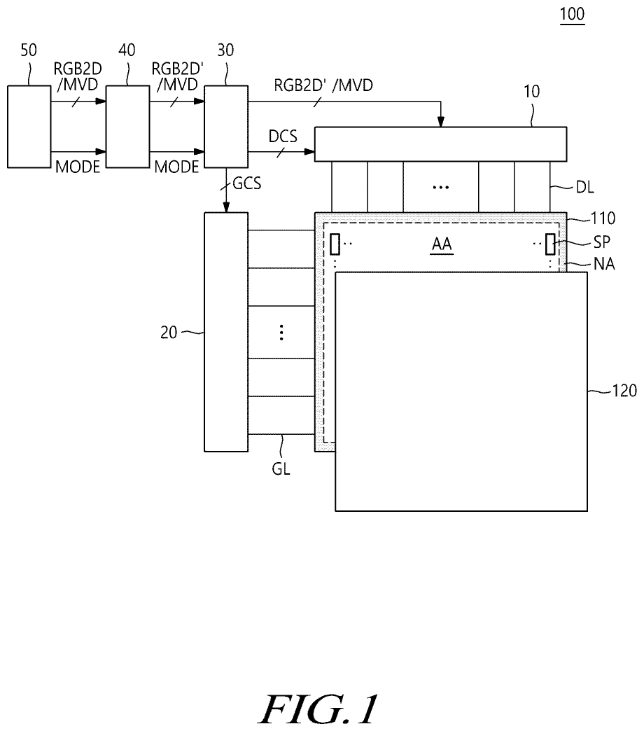

FIG. 1 is a block diagram illustrating a system of a stereoscopic image display device according to an embodiment of the disclosure.

Referring to FIG. 1, a stereoscopic image display device 100 according to an embodiment of the disclosure can include a display panel 110, a lens unit 120, a data driving circuit 10, a gate driving circuit 20, a timing controller 30, an image processing unit 40, and a host system 50.

The display panel 110 can include a display area (or active area) AA in which images are displayed and a non-display area (or non-active area) NA in which no image is displayed. The non-display area NA can be an outer area of the display area AA and be referred to as a bezel area.

In an embodiment, the non-display area NA can entirely surround the display area AA. However, in another embodiment, the non-display area NA can only surround a portion of the display area AA.

The display panel 110 can include a plurality of subpixels SP. The display panel 110 can further include various types of signal lines to drive the plurality of subpixels SP.

The lens unit 120 can advance the first to nth (where n is a natural number) view images displayed on the subpixels SP of the display panel 110 to the first to nth view areas, respectively. In other words, the lens unit 120 can advance the tth (where t is a natural number meeting 1≤t≤n) view image Vt displayed on the subpixels SP to the tth view area VPt.

The lens unit 120 in this embodiment can be formed of a lenticular lens, but is not limited to the example.

The lens unit 120 can be disposed in a slanted type or a vertical type. The slanted type is a type in which the lens unit 120 is disposed to be slanted at a predetermined angle with respect to the subpixels SP of the display panel 110, and the vertical type is a type in which the lens unit 120 is disposed to be parallel to a length direction (or vertical direction) of the subpixels SP of the display panel 110. The following description focuses primarily on an embodiment in which the lens unit 120 is disposed in the slanted type, but the disclosure is not limited thereto.

The data driving circuit 10 can include a plurality of source drive integrated circuits (hereinafter, referred to as ‘ICs’). Additionally, the source drive ICs can convert 2D conversion image data RGB2D′ or multi-view image data MVD into a positive/negative gamma compensation voltage to generate positive/negative analog data voltages under the control of the timing controller 30. The data voltages output from the source drive ICs can be supplied to the data lines DL of the display panel 110.

The gate driving circuit 20 can sequentially supply gate pulses (or scan pulses) synchronized to data voltages to the gate lines GL of the display panel 110 under the control of the timing controller 30. Further, the gate driving unit 110 can include a plurality of gate drive integrated circuits each including a shift register, a level shifter for converting the output signal of the shift register into a swing width suitable for driving the TFT of the display panel 110, and an output buffer.

The timing controller 30 can receive 2D conversion image data RGB2D′ or multi-view image data MVD′, timing signals, and a mode signal MODE from the image processing unit 40. The timing signals can include, e.g., a vertical synchronization signal, a horizontal synchronization signal, a data enable signal, and a clock signal.

The timing controller 30 can generate a data control signal DCS for controlling the data driving circuit 10 based on the 2D conversion image data RGB2D′ and timing signals. Additionally, the timing controller 30 can generate a gate control signal GCS for controlling the gate driving circuit 20 in a 2D mode.

The timing controller 30 can generate a data control signal DCS for controlling the data driving circuit 10 based on the multi-view image data MVD and the timing signals and generate a gate control signal GCS for controlling the gate driving circuit 20 in a 3D mode.

The timing controller 30 can supply the gate control signal GCS to the gate driving circuit 20. The timing controller 30 supplies 2D converted image data (RGB2D′) and data control signal (DCS) to the data driving circuit 10 in the 2D mode, and multi-view image data (MVD) and data control signal (DCS) in the 3D mode. DCS can be supplied to the data driving circuit 10 by the timing controller 30.

The host system 50 can include a system on chip in which a scaler is embedded to convert 2D image data RGB2D or multi-view image data MVD input from an external video source device into a data format having a resolution suitable for displaying on the display panel 110.

The host system 50 can supply 2D image data RGB2D or multi-view image data MVD and timing signals to the image processing unit 40 through an interface such as a low voltage differential signaling (LVDS) interface, a transition minimized differential signaling (TMDS) interface, or the like, however, the present disclosure is not limited thereto.

The host system 50 can supply the 2D image data RGB2D and timing signals to the image processing unit 40 in the 2D mode, and can supply the multi-view image data MVD and timing signals to the image processing unit 40 in the 3D mode. Further, the host system 50 can supply a mode signal MODE capable of distinguishing between the 2D mode and the 3D mode to the image processing unit 40.

Next, the image processing unit 40 can distinguish between the 2D mode and the 3D mode according to the mode signal MODE. The image processing unit 40 can receive the 2D image data RGB2D from the host system 50 in the 2D mode.

Additionally, the image processing unit 40 can output, to the timing controller 30, the 2D conversion image data RGB2D′ obtained by converting the first to nth subpixel SP data supplied to the first to nth subpixels SP displaying the image proceeding to the first to nth view areas in the 2D mode to be reflected to all of the at least one subpixel SP data among the first to nth subpixel SP data.

The image processing unit 40 can receive multi-view image data MVD from the host system 50 in the 3D mode. The image processing unit 40 can output the multi-view image data MVD to the timing controller 30 without converting the multi-view image data MVD in the 3D mode.

In an embodiment, the host system 50 and the image processing unit 40 can be provided as one component. For example, the one component can be configured to convert 2D image data RGB2D or multi-view image data MVD input from an external video source device into a data format having a resolution suitable for displaying on the display panel 110, and can also be configured to output, to the timing controller 30, the 2D conversion image data RGB2D′ obtained by converting the first to nth subpixel SP data supplied to the first to nth subpixels SP displaying the image proceeding to the first to nth view areas in the 2D mode to be reflected to all of the at least one subpixel SP data among the first to nth subpixel SP data. However, the present disclosure is not limited thereto.

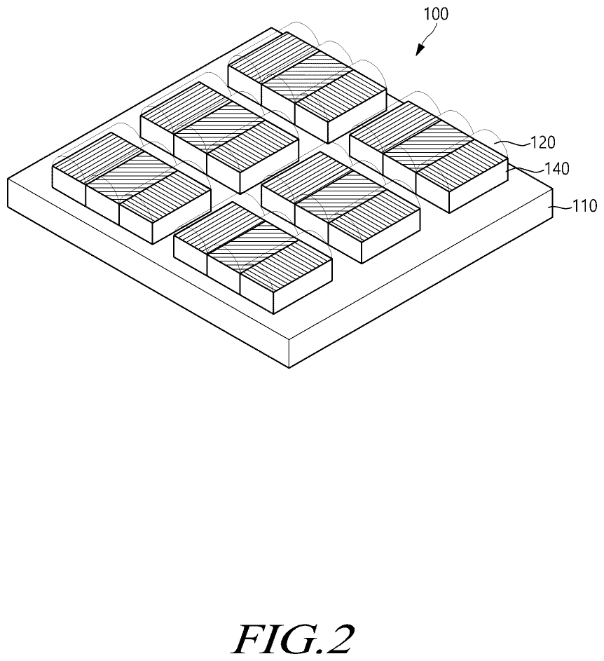

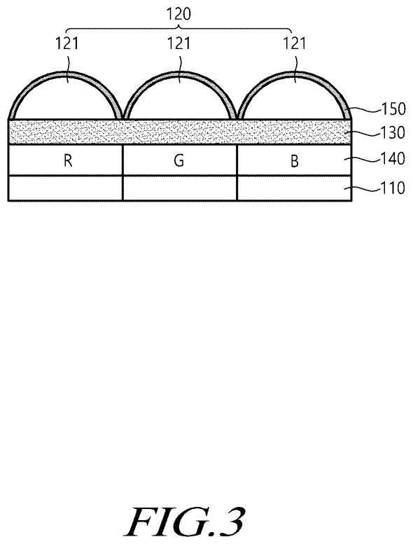

FIG. 2 is a perspective view illustrating a configuration of a stereoscopic image display device according to an embodiment of the disclosure, and FIG. 3 is a cross-sectional view illustrating a stereoscopic image display device according to an embodiment of the disclosure.

Referring to FIGS. 2 to 3, a stereoscopic image display device 100 can include a display panel 110, a lens unit 120, and an adhesive layer 130.

The display panel 110 displays an image and can be a micro light emitting element display panel. Hereinafter, in the present embodiment, it is described that the display panel 110 is a micro light-emitting diode (LED) display panel, but the disclosure is not limited thereto. For example, the display panel 110 can include a liquid crystal display panel, an organic electroluminescence display panel, an electrophoretic display panel, a quantum dot display panel, a mini light emitting element display panel, or the like.

A plurality of subpixels SP can be disposed on the display panel 110, and light can be emitted from each subpixel SP. For example, the display panel 110 can include a plurality of pixel areas and non-pixel areas disposed around the pixel areas. The pixel area can be an area in which circuit elements and light emitting elements constituting the subpixel SP are formed. The non-pixel area is an area in which the subpixels SP are not disposed, and can include a boundary between adjacent subpixels SP and/or a non-display area NA. Additionally, the pixel area can be disposed in the display area AA.

The light emitting element according to the present embodiment can be the micro LED 140, and the micro LED 140 can be independently disposed in each pixel area. For example, the micro LED 140 disposed in the pixel area can emit red, green, and blue light. However, the micro LED 140 is not limited thereto, and can be configured to emit any visible color of light.

The image emitted from each subpixel SP and input to a left eye and the right eye of the user can have different pieces of ray information (e.g., intensity, color, and direction of the image), and a 3D image can be implemented to the viewer by the different pieces of information.

The lens unit 120 is configured to implement a stereoscopic image by separating the optical axes of a left and right parallax images, and can be disposed on one surface of the display panel 110. For example, the lens unit 120 can be disposed on a display surface on which light is output from the display panel 110, and can include a plurality of lenticular lenses 121 having a hemispherical shape. However, in another embodiment, the lenticular lenses 121 can have an extended semi-circle shape. Additionally, the micro LED 140 can be disposed between the display panel 110 and the lens unit 120. Further, the lenticular lenses 121 can correspond to the micro LED 140. Accordingly, each micro LED 140 can include a lenticular lens 121 disposed thereon.

The plurality of lenticular lenses 121 can be formed of a transparent resin, and can be disposed in the pixel areas, respectively. As described above, as the lenticular lens 121 is independently disposed in each pixel area, the two-dimensional image output from the display panel 110 passes through the lenticular lens 121, and the left-eye image and the right-eye image are respectively incident on the left eye and the right eye of the viewer, and the viewer can appreciate the three-dimensional image by recognizing them as the three-dimensional image due to binocular parallax.

Additionally, the adhesive layer 130 is for attaching the display panel 110 and the lens unit 120, and can be disposed between the display panel 110 and the lens unit 120. For example, the adhesive layer 130 can include optically clear adhesive (OCA) or optically clear resin (OCR) having good light transmittance. In another embodiment, the adhesive layer 130 can be disposed between the micro LED 140 and the lens unit 120.

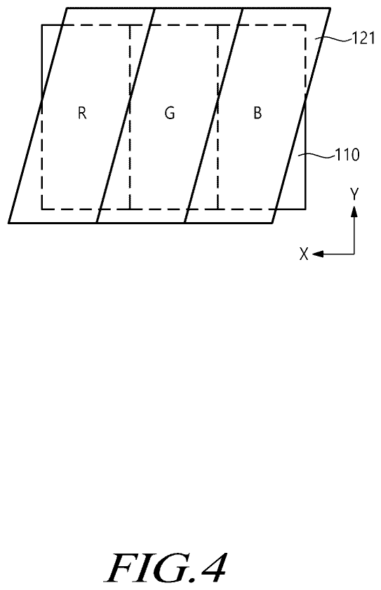

FIG. 4 is a plan view illustrating a lens unit disposed in a pixel area according to an embodiment of the disclosure.

Referring to FIG. 4, the lenticular lens 121 can be disposed to be inclined from the display panel 110 at a predetermined angle. For example, the lenticular lens 121 can be disposed to have an inclination of e.g., −25° to +25° with respect to the major axis direction Y of the subpixel SP provided in the display panel 110. Here, “−” can mean an inclination in the counterclockwise direction, and “+” can mean an inclination in the clockwise direction.

However, in another embodiment, the lenticular lens 121 can be disposed to have a different inclination. Additionally, in an embodiment, the inclination in the counterclockwise direction and the inclination in the clockwise direction does not have to be equal to each other.

As the lenticular lens 121 is disposed to be inclined with respect to the major axis direction Y of the subpixel SP provided in the display panel 110, the number of views for viewing the stereoscopic image can be appropriately adjusted.

The display device according to the present embodiment can further include an anti-reflection layer 150 coated on the lens unit 120.

The anti-reflection layer 150 is for preventing a decrease in visibility due to image formation of external light, and can be formed by applying a coating liquid having a low refractive index of e.g., 1.3 to 1.5 to one surface of the lens unit 120. For example, the anti-reflection layer 150 can be formed of an inorganic compound such as calcium fluoride (CaF2), zinc sulfide (ZnS), and silica (SiO2), however the present disclosure is not limited thereto.

As described above, as the anti-reflection layer 150 is provided on the lens unit 120, it is possible to reduce the reflectance of external light to prevent glare while enhancing visibility. Accordingly, the 3D effect generated by the stereoscopic image display device 100 can be maintained without distortion, and image quality can be improved.

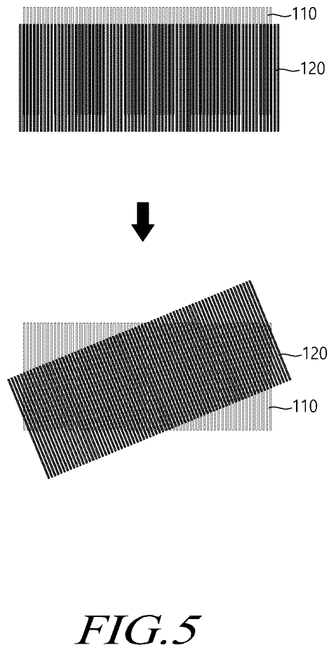

FIG. 5 is a view schematically illustrating moiré interference depending on the presence or absence of a slope of a lens unit.

Moiré interference refers to a phenomenon in which a pattern larger than a pattern before overlapping is generated when periodic patterns overlap, and the pattern that is generated in this case is called a moiré pattern.

Referring to FIG. 5, when the lens unit 120 disposed on the display panel 110 is disposed in the vertical type, the subpixel SP and the lens unit 120 are parallel and overlap, resulting in moiré interference.

However, when the lens unit 120 disposed on the display panel 110 is disposed in the slanted type, the subpixel SP and the lens unit 120 do not overlap each other, and the distance between the subpixel SP and the lens unit 120 can be widened or narrowed to avoid moiré interference. Accordingly, it is possible to provide a stereoscopic image display device 100 with reduced moiré pattern generation.

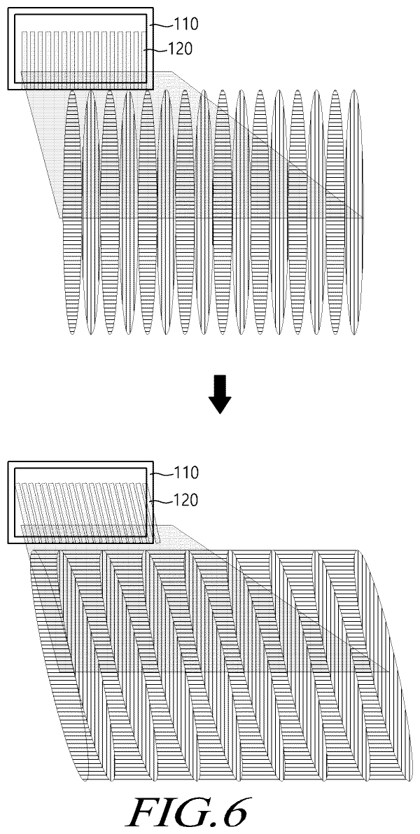

FIG. 6 is a view schematically illustrating view switching depending on the presence or absence of a slope of a lens unit.

Referring to FIG. 6, when the lens unit 120 disposed on the display panel 110 is disposed in the vertical type, the view boundary is identified, causing the image to look stuttering or unnatural during view switching. In contrast, when the lens unit 120 disposed on the display panel 110 is disposed in the slanted type, the view boundary is unclear, making image switching smooth during view switching. Accordingly, the 3D effect generated display panel 110 can be made to look more natural, with smoother image switching during view switching.

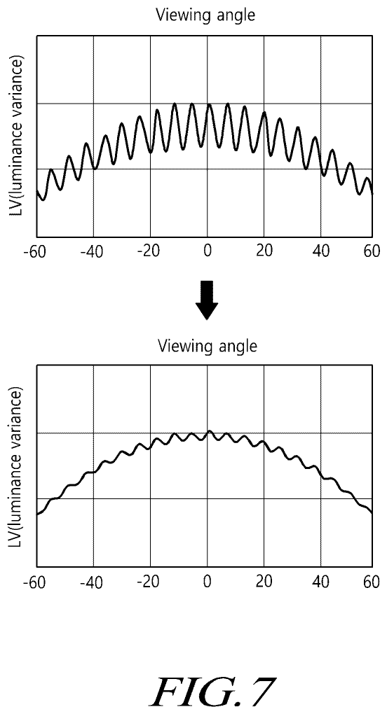

FIG. 7 is a view schematically illustrating a luminance variance per viewing angle depending on the presence or absence of a slope of a lens unit.

Referring to FIG. 7, when the lens unit 120 disposed on the display panel 110 is disposed in the vertical type, it can be identified that the luminance variance according to the viewing angle change is significant. This is why the aperture area and non-aperture area of the subpixel SP enlarged by the lens unit 120 regularly appear. In contrast, when the lens unit 120 disposed on the display panel 110 is disposed in the slanted type, the aperture area and the non-aperture area of the subpixel SP is irregularly enlarged, so that the luminance variance per viewing angle can be decreased, thereby improving 3D image quality.

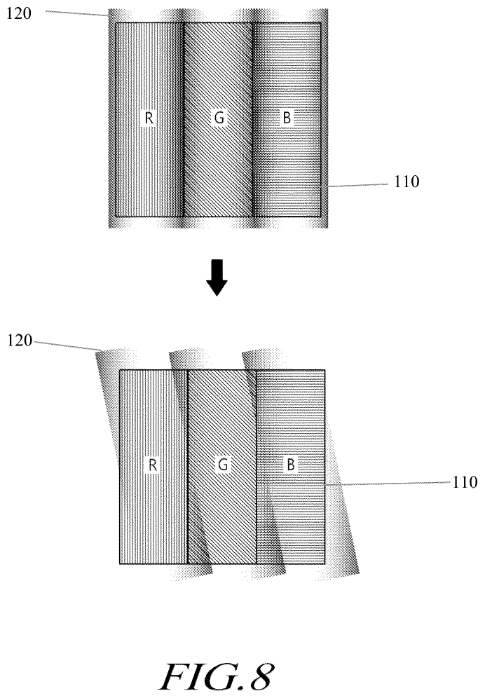

FIG. 8 is a view schematically illustrating a view map depending on the presence or absence of a slope of a lens unit.

Referring to FIG. 8, when the lens unit 120 disposed on the display panel 110 is disposed in the vertical type, the view map can be uniformized in the length direction of the subpixel SP. In contrast, when the lens unit 120 disposed on the display panel 110 is disposed in the slanted type, the view map can be subdivided in various directions, rendering it possible to configure various view maps depending on angle settings of the lens unit 120. Accordingly, the view maps can be better blended together, thereby decreasing the image looking stuttering or unnatural during view switching.

Embodiments of the disclosure described above are briefly described below.

According to an embodiment of the present disclosure, there can be provided a stereoscopic image display device comprising a display panel displaying an image, a lens unit disposed on one surface of the display panel, formed to be inclined at a preset angle from the display panel, and an adhesive layer disposed between the display panel and the lens unit.

According to embodiments of the present disclosure, the display panel can include a pixel area and a non-pixel area disposed around the pixel area. The lens unit can be disposed in the pixel area.

According to embodiments of the present disclosure, a micro light emitting diode (LED) can be independently disposed in the pixel area.

According to embodiments of the present disclosure, the lens unit can include a plurality of lenticular lenses having a hemispherical shape.

According to embodiments of the present disclosure, the lens unit can be disposed to have an inclination of e.g., −25° to +25° with respect to a major axis direction of a subpixel provided in the display panel.

According to embodiments of the present disclosure, the adhesive layer can include an optically clear adhesive (OCA) or an optically clear resin (OCR).

According to various embodiments of the present disclosure, the stereoscopic image display device can further include an anti-reflection layer coated on the lens unit.

According to embodiments of the present disclosure, the anti-reflection layer can have a refractive index of e.g., 1.3 to 1.5.

According to an embodiment of the present disclosure, there can be provided a stereoscopic image display device including a display panel including a pixel area and a non-pixel area disposed around the pixel area, a lens unit disposed on one surface of the display panel, independently disposed in the pixel area, and an adhesive layer disposed between the display panel and the lens unit.

According to embodiments of the present disclosure, the lens unit can be formed to be inclined at a preset angle with respect to a major axis direction of a subpixel provided in the display panel.

According to embodiments of the present disclosure, the preset angle can include e.g., −25° to +25°.

According to embodiments of the present disclosure, the lens unit can include a plurality of lenticular lenses having a hemispherical shape.

According to embodiments of the present disclosure, a micro light emitting diode (LED) can be independently disposed in the pixel area.

According to various embodiments of the present disclosure, the stereoscopic image display device can further include an anti-reflection layer coated on the lens unit.

According to embodiments of the disclosure, the anti-reflection layer can have a refractive index of e.g., 1.3 to 1.5.

The above description has been presented to enable any person skilled in the art to make and use the technical idea of the disclosure, and has been provided in the context of a particular application its and requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A stereoscopic image display device, comprising:
a display panel configured to display an image; and
a lens unit disposed on one surface of the display panel, and disposed to be inclined at a preset angle from the display panel,
wherein the lens unit is configured to implement a stereoscopic image.

2. The stereoscopic image display device of claim 1, wherein the display panel includes a pixel area and a non-pixel area disposed around the pixel area, and
wherein the lens unit is disposed in the pixel area.

3. The stereoscopic image display device of claim 2, further comprising a micro light emitting diode (LED) independently disposed in the pixel area.

4. The stereoscopic image display device of claim 1, wherein the lens unit includes a plurality of lenticular lenses having a semi-circle shape.

5. The stereoscopic image display device of claim 1, wherein the preset angle is an angle with an inclination in a range of approximately −25° to +25° with respect to a major axis direction of a subpixel provided in the display panel.

6. The stereoscopic image display device of claim 1, further comprising an adhesive layer disposed between the display panel and the lens unit,
wherein the adhesive layer includes an optically clear adhesive (OCA) or an optically clear resin (OCR).

7. The stereoscopic image display device of claim 1, further comprising an anti-reflection layer disposed on the lens unit.

8. The stereoscopic image display device of claim 7, wherein the anti-reflection layer has a refractive index in a range of approximately 1.3 to 1.5.

9. A stereoscopic image display device, comprising:
a display panel configured to display an image, the display panel including a pixel area and a non-pixel area disposed adjacent to the pixel area; and
a lens unit disposed on one surface of the display panel, and independently disposed in the pixel area,
wherein the lens unit is configured to implement a stereoscopic image, and
wherein the lens unit is disposed outside of the display panel.

10. The stereoscopic image display device of claim 9, wherein the lens unit is disposed to be inclined at a preset angle with respect to a major axis direction of a subpixel provided in the display panel.

11. The stereoscopic image display device of claim 10,
wherein the preset angle is in a range of approximately −25° to +25°.

12. The stereoscopic image display device of claim 9, wherein the lens unit includes a plurality of lenticular lenses having a semi-circle shape.

13. The stereoscopic image display device of claim 9, further comprising a micro light emitting diode (LED) independently disposed in the pixel area.

14. The stereoscopic image display device of claim 9, further comprising an anti-reflection layer disposed on the lens unit.

15. The stereoscopic image display device of claim 14, wherein the anti-reflection layer has a refractive index in a range of approximately 1.3 to 1.5.

16. A stereoscopic image display device, comprising:
a display panel configured to display an image;
a plurality of micro light emitting diodes (LEDs) disposed on the display panel; and
a plurality of lenticular lenses disposed on the display panel,
wherein the plurality of lenticular lenses are configured to implement a stereoscopic image.

17. The stereoscopic image display device of claim 16, wherein the plurality of lenticular lenses are inclined at a preset angle from the display panel.

18. The stereoscopic image display device of claim 16, wherein the plurality of lenticular lenses have a semi-circle shape.

19. The stereoscopic image display device of claim 16, wherein the plurality of LEDs are disposed between the display panel and the plurality of lenticular lenses.

20. The stereoscopic image display device of claim 19, further comprising an adhesive layer disposed between the plurality of LEDs and the plurality of lenticular lenses.
